(19) United States
(12) Patent Application Publication
(10) Pub. No.: US 2009/0225580 A1
(43) Pub. Date: Sep. 10, 2009

(54) Integrated Circuit, Memory Module, and Method of Manufacturing an Integrated Circuit

(76) Inventors: Peng-Fei Wang, Dresden (DE); Gill Yong Lee, Dresden (DE); Lothar Risch, Neubiberg (DE)

Correspondence Address: SLATER & MATSIL, L.L.P., 17950 PRESTON ROAD, SUITE 1000, DALLAS, TX, 75252, US

(21) Appl. No.: 12/044,849

(22) Filed: Mar. 7, 2008

(51) Int. Cl. G11C 5/06; H01L 21/71

(52) U.S. Cl. 365/63; 438/430; 257/E21.536

(57) ABSTRACT

An integrated circuit includes a plurality of memory cells, each memory cell including a memory element and a select device; and a plurality of word lines and bit lines connected to the memory cells. The bit lines, word lines, and the memory elements are arranged above the select devices.

### BACKGROUND

Integrated circuits including memory cells are known. It is desirable to improve such integrated circuits.

### SUMMARY OF THE INVENTION

According to one embodiment of the present invention, an integrated circuit is provided, including a plurality of memory cells, each memory cell including a memory element and a select device, and a plurality of word lines and bit lines connected to the memory cells, wherein the bit lines, the word lines, and the memory elements are arranged above the select devices.

According to one embodiment of the present invention, a method of manufacturing an integrated circuit is provided, including forming a semiconductor substrate including a plurality of select devices; forming a plurality of memory elements; forming a plurality of word lines and bit lines, wherein the memory elements, the word lines and the bit lines are formed above the semiconductor substrate.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic cross-sectional view of a magneto-resistive memory element;

FIG. 2 shows a schematic drawing of a circuit usable in conjunction with the memory element shown in FIG. 1;

FIG. 3A shows a schematic cross-sectional view of a programmable metallization element set to a first switching state;

FIG. 3B shows a schematic cross-sectional view of a programmable metallization element set to a second switching state;

FIG. 4 shows a schematic cross-sectional view of a phase changing memory element;

FIG. 5 shows a schematic drawing of an integrated circuit;

FIG. 6A shows a schematic cross-sectional view of a carbon memory element set to a first switching state;

FIG. 6B shows a schematic cross-sectional view of a carbon memory element set to a second switching state;

FIG. 7A shows a schematic drawing of an integrated circuit including resistivity changing memory elements;

FIG. 7B shows a schematic drawing of an integrated circuit including resistivity changing memory elements;

FIG. 8 shows a schematic cross-sectional view of an integrated circuit according to one embodiment of the present invention;

FIG. 9 shows a flowchart of a method of manufacturing an integrated circuit according to one embodiment of the present invention;

FIG. 10 shows a schematic top view and schematic cross-sectional views of a manufacturing stage of a method of manufacturing an integrated circuit according to one embodiment of the present invention;

FIG. 11 shows a schematic top view and schematic cross-sectional views of a manufacturing stage of a method of manufacturing an integrated circuit according to one embodiment of the present invention;

FIG. 12 shows a schematic top view and schematic cross-sectional views of a manufacturing stage of a method of manufacturing an integrated circuit according to one embodiment of the present invention;

FIG. 13 shows a schematic top view and schematic cross-sectional views of a manufacturing stage of a method of manufacturing an integrated circuit according to one embodiment of the present invention;

FIG. 14 shows a schematic top view and schematic cross-sectional views of a manufacturing stage of a method of manufacturing an integrated circuit according to one embodiment of the present invention;

FIG. 15 shows a schematic top view and schematic cross-sectional views of a manufacturing stage of a method of manufacturing an integrated circuit according to one embodiment of the present invention;

FIG. 16 shows a schematic top view and schematic cross-sectional views of a manufacturing stage of a method of manufacturing an integrated circuit according to one embodiment of the present invention;

FIG. 17 shows a schematic top view and schematic cross-sectional views of a manufacturing stage of a method of manufacturing an integrated circuit according to one embodiment of the present invention;

FIG. 18 shows a schematic top view and schematic cross-sectional views of a manufacturing stage of a method of manufacturing an integrated circuit according to one embodiment of the present invention;

FIG. 19 shows a schematic top view and schematic cross-sectional views of a manufacturing stage of a method of manufacturing an integrated circuit according to one embodiment of the present invention;

FIG. 20 shows a schematic top view and schematic cross-sectional views of a manufacturing stage of a method of manufacturing an integrated circuit according to one embodiment of the present invention;

FIG. 21 shows a schematic top view and schematic cross-sectional views of a manufacturing stage of a method of manufacturing an integrated circuit according to one embodiment of the present invention;

FIG. 22 shows a schematic top view and schematic cross-sectional views of a manufacturing stage of a method of manufacturing an integrated circuit according to one embodiment of the present invention;

FIG. 23 shows a schematic top view and schematic cross-sectional views of a manufacturing stage of a method of manufacturing an integrated circuit according to one embodiment of the present invention;

FIG. 24 shows a schematic top view and schematic cross-sectional views of a manufacturing stage of a method of manufacturing an integrated circuit according to one embodiment of the present invention;

FIG. 25 shows a schematic top view and schematic cross-sectional views of a manufacturing stage of a method of manufacturing an integrated circuit according to one embodiment of the present invention;

FIG. 26 shows a schematic top view and schematic cross-sectional views of a manufacturing stage of a method of manufacturing an integrated circuit according to one embodiment of the present invention;

FIG. 27 shows a schematic top view and schematic cross-sectional views of a manufacturing stage of a method of manufacturing an integrated circuit according to one embodiment of the present invention;

FIG. 28 shows a schematic top view and schematic cross-sectional views of a manufacturing stage of a method of manufacturing an integrated circuit according to one embodiment of the present invention;

FIG. 29 shows a schematic top view and schematic cross-sectional views of a manufacturing stage of a method of manufacturing an integrated circuit according to one embodiment of the present invention;

FIG. 30 shows a schematic top view and schematic cross-sectional views of a manufacturing stage of a method of manufacturing an integrated circuit according to one embodiment of the present invention;

FIG. 31 shows a schematic drawing of an integrated circuit according to one embodiment of the present invention;

FIG. 32 shows a schematic cross-sectional view of an integrated circuit according to one embodiment of the present invention;

FIG. 33 shows a schematic cross-sectional view of an integrated circuit according to one embodiment of the present invention;

FIG. 34A shows a schematic perspective view of a memory module according to one embodiment of the present invention; and

FIG. 34B shows a schematic perspective view of a memory module according to one embodiment of the present invention.

### DETAILED DESCRIPTION OF ILLUSTRATIVE EMBODIMENTS

In the following description, some examples of memory elements which may be used in embodiments of integrated circuits/methods of manufacturing integrated circuits according to the present invention will be explained. Of course, the following examples are not to be understood as being limiting; also other types of memory elements may be used.

According to one embodiment of the present invention, magneto-resistive memory elements may be used. Magneto-resistive memory elements involve spin electronics, which combines semiconductor technology and magnetics. Digital information, represented as a “0” or “1” is stored in the alignment of magnetic moments. The resistance of the magnetic component depends on the moment's alignment. The stored state is read from the element by detecting the component's resistive state.

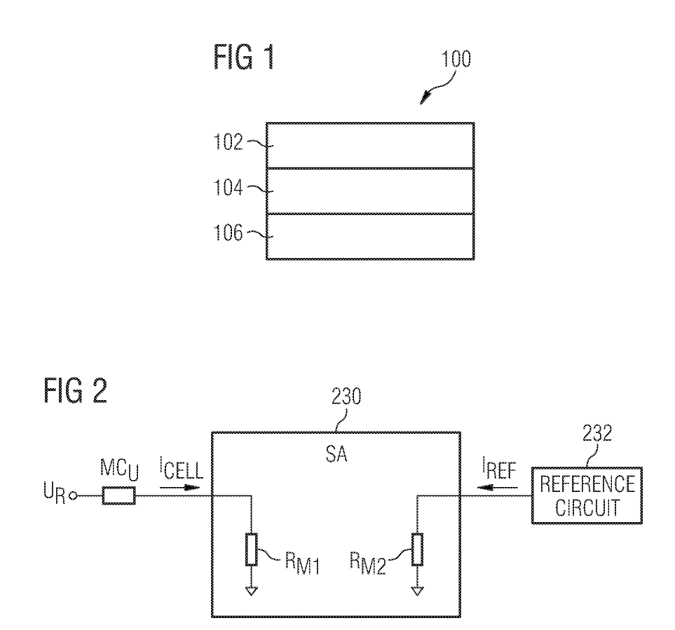

FIG. 1 illustrates a perspective view of a MRAM element 100 having a soft layer 102, a tunnel layer 104, and a hard (“pinned”) layer 106, for example. Soft layer 102 and hard layer 106 may respectively include a plurality of magnetic metal layers, for example, eight to twelve layers of materials such as PtMn, CoFe, Ru, and NiFe, and the like. A logic state is represented by the magnetization directions of the soft layer 102 and the hard layer 106.

In order to read the logic state stored in an unknown memory element MCu like the MRAM element 100, a schematic such as the one shown in FIG. 2, including a sense amplifier (SA) 230, may be used. A reference voltage U_{R} is applied to one end of the unknown memory cell MCu. The other end of the unknown memory cell MCu is coupled to a measurement resistor Rm1. The other end of the measurement resistor Rₘ₁ is coupled to ground. The current running through the unknown memory cell MCu is equal to current I_{cell}. A reference circuit 232 supplies a reference current I_{ref} that is run into measurement resistor Rₘ₂. The other end of the measurement resistor Rₘ₂ is coupled to ground, as shown.

According to one embodiment of the present invention, programmable metallization elements (PMC), also known as solid electrolyte elements like CBRAM (conductive bridging random access memory) elements, may be used, an example thereof being described in the following.

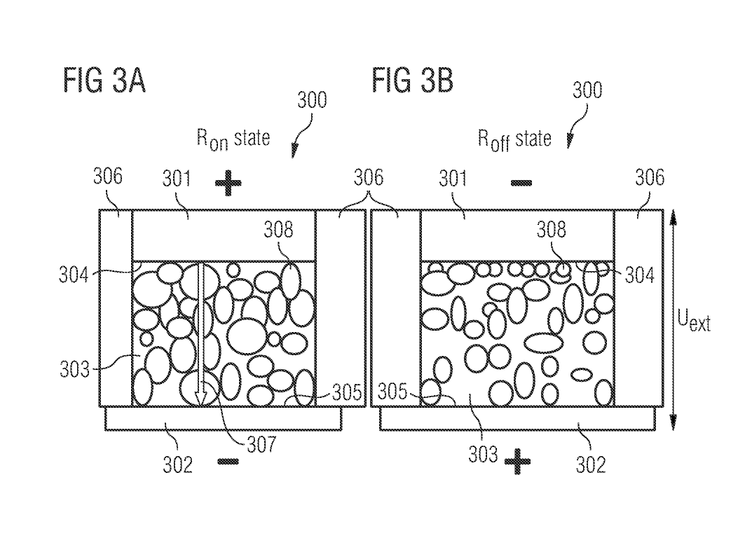

As shown in FIG. 3A, a CBRAM element 300 includes a first electrode 301, a second electrode 302, and a solid electrolyte block (in the following also referred to as ion conductor block) 303 which includes the active material and which is sandwiched between the first electrode 301 and the second electrode 302. This solid electrolyte block 303 can also be shared between a plurality of memory elements (not shown here). The first electrode 301 contacts a first surface 304 of the ion conductor block 303, the second electrode 302 contacts a second surface 305 of the ion conductor block 303. The ion conductor block 303 is isolated against its environment by an isolation structure 306. The first surface 304 usually is the top surface, the second surface 305 the bottom surface of the ion conductor 303. In the same way, the first electrode 301 generally is the top electrode, and the second electrode 302 the bottom electrode of the CBRAM element. One of the first electrode 301 and the second electrode 302 is a reactive electrode, the other one an inert electrode. Here, the first electrode 301 is the reactive electrode, and the second electrode 302 is the inert electrode. In this example, the first electrode 301 includes silver (Ag), the ion conductor block 303 includes silver-doped chalcogenide material, the second electrode 302 includes tungsten (W), and the isolation structure 306 includes SiO₂ or Si₃N₄. The present invention is however not restricted to these materials. For example, the first electrode 301 may alternatively or additionally include copper (Cu) or zinc (Zn), and the ion conductor block 303 may alternatively or additionally include copper-doped chalcogenide material. Further, the second electrode 302 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned materials, and can also include alloys of the aforementioned materials. The thickness of the ion conductor 303 may, for example, range between about 5 nm and about 500 nm. The thickness of the first electrode 301 may, for example, range between about 10 nm and about 100 nm. The thickness of the second electrode 302 may, for example, range between about 5 nm and about 500 nm, between about 15 nm to about 150 nm, or between about 25 nm and about 100 nm. It is to be understood that the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 3A is applied across the ion conductor block 303, a redox reaction is initiated which drives Ag⁺ ions out of the first electrode 301 into the ion conductor block 303 where they are reduced to Ag, thereby forming Ag rich clusters 308 within the ion conductor block 303. If the voltage applied across the ion conductor block 303 is applied for an enhanced period of time, the size and the number of Ag rich clusters within the ion conductor block 303 is increased to such an extent that a conductive bridge 307 between the first electrode 301 and the second electrode 302 is formed. In case that a voltage is applied across the ion conductor 303 as shown in FIG. 3B (inverse voltage compared to the voltage applied in FIG. 3A), a redox reaction is initiated which drives Ag⁺ ions out of the ion conductor block 303 into the first electrode 301 where they are reduced to Ag. As a consequence, the size and the number of Ag rich clusters within the ion conductor block 303 are reduced, thereby erasing the conductive bridge 307. After having applied the voltage/inverse voltage, the memory element 300 remains within the corresponding defined switching state even if the voltage/inverse voltage has been removed.

In order to determine the current memory status of a CBRAM element, for example, a sensing current is routed through the CBRAM element. The sensing current experiences a high resistance in case no conductive bridge 307 exists within the CBRAM element, and experiences a low resistance in case a conductive bridge 307 exists within the CBRAM element. A high resistance may, for example, represent “0”, whereas a low resistance represents “1”, or vice versa. The memory status detection may also be carried out using sensing voltages. Alternatively, a sensing voltage may be used in order to determine the current memory status of a CBRAM element.

According to one embodiment of the invention, the memory elements are phase changing memory elements that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory elements may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory element, a sensing current may routed through the phase changing material (or a sensing voltage may be applied across the phase changing material), thereby sensing the resistivity of the resistivity changing memory element, which represents the memory state of the memory element.

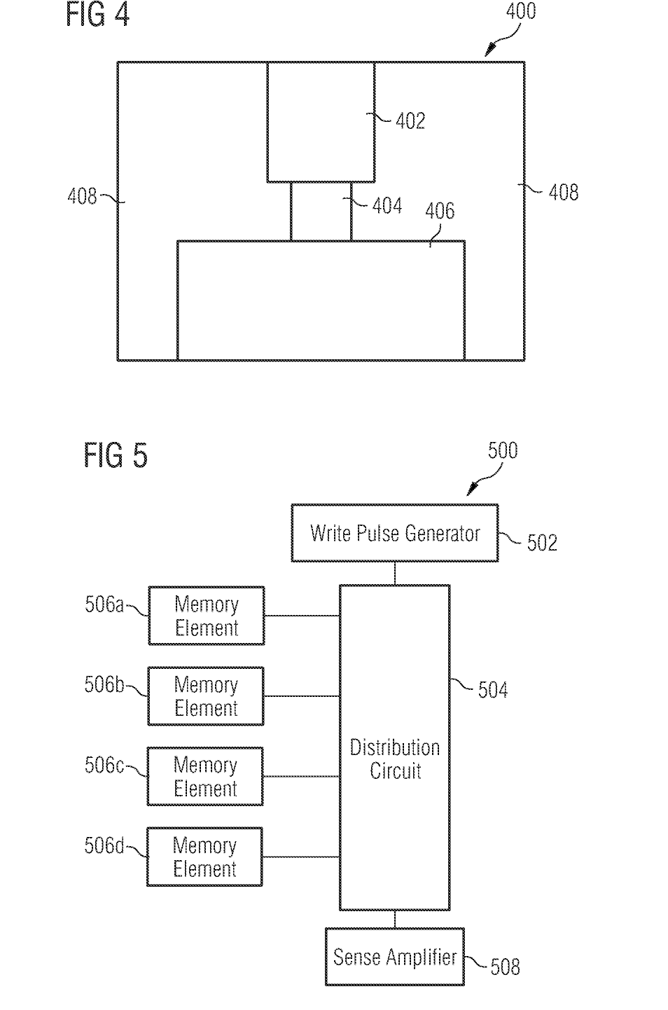

FIG. 4 illustrates a cross-sectional view of an exemplary phase changing memory element 400 (active-in-via type). The phase changing memory element 400 includes a first electrode 402, a phase changing material 404, a second electrode 406, and an insulating material 408. The phase changing material 404 is laterally enclosed by the insulating material 408. To use the phase changing memory element, a selection device (not shown), such as a transistor, a diode, or another active device, may be coupled to the first electrode 402 or to the second electrode 406 to control the application of a current or a voltage to the phase changing material 404 via the first electrode 402 and/or the second electrode 406. To set the phase changing material 404 to the crystalline state, a current pulse and/or voltage pulse may be applied to the phase changing material 404, wherein the pulse parameters are chosen such that the phase changing material 404 is heated above its crystallization temperature, while keeping the temperature below the melting temperature of the phase changing material 404. To set the phase changing material 404 to the amorphous state, a current pulse and/or voltage pulse may be applied to the phase changing material 404, wherein the pulse parameters are chosen such that the phase changing material 404 is quickly heated above its melting temperature, and is quickly cooled.

The phase changing material 404 may include a variety of materials. According to one embodiment, the phase changing material 404 may include or consist of a chalcogenide alloy that includes one or more elements from group VI of the periodic table. According to another embodiment, the phase changing material 404 may include or consist of a chalcogenide compound material, such as GeSbTe, SbTe, GeTe or AgInSbTe. According to a further embodiment, the phase changing material 404 may include or consist of chalcogen free material, such as GeSb, GaSb, InSb, or GeGaInSb. According to still another embodiment, the phase changing material 404 may include or consist of any suitable material including one or more of the elements Ge, Sb, Te, Ga, Bi, Pb, Sn, Si, P, O, As, In, Se, and S.

According to one embodiment, at least one of the first electrode 402 and the second electrode 406 may include or consist of Ti, V, Cr, Zr, Nb, Mo, Hf, Ta, W, or mixtures or alloys thereof. According to another embodiment, at least one of the first electrode 402 and the second electrode 406 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TIAlN, TiSiN, W—Al₂O₃ and Cr—Al₂O₃.

FIG. 5 illustrates a block diagram of a memory device 500 including a write pulse generator 502, a distribution circuit 504, phase changing memory elements 506a, 506b, 506c, 506d (for example phase changing memory elements 400 as shown in FIG. 2), and a sense amplifier 508. According to one embodiment, the write pulse generator 502 generates current pulses or voltage pulses that are supplied to the phase changing memory elements 506a, 506b, 506c, 506d via the distribution circuit 504, thereby programming the memory states of the phase changing memory elements 506a, 506b, 506c, 506d. According to one embodiment, the distribution circuit 504 includes a plurality of transistors that supply direct current pulses or direct voltage pulses to the phase changing memory elements 506a, 506b, 506c, 506d or to heaters being disposed adjacent to the phase changing memory elements 506a, 506b, 506c, 506d.

As already indicated, the phase changing material of the phase changing memory elements 506a, 506b, 506c, 506d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 508 is capable of determining the memory state of one of the phase changing memory elements 506a, 506b, 506c, or 506d in dependence on the resistance of the phase changing material.

To achieve high memory densities, the phase changing memory elements 506a, 506b, 506c, 506d may be capable of storing multiple bits of data, i.e., the phase changing material may be programmed to more than two resistance values. For example, if a phase changing memory element 506a, 506b, 506c, 506d is programmed to one of three possible resistance levels, 1.5 bits of data per memory element can be stored. If the phase changing memory element is programmed to one of four possible resistance levels, two bits of data per memory element can be stored, and so on.

The embodiment shown in FIG. 5 may also be applied in a similar manner to other types of memory elements like resistivity changing memory elements like programmable metallization elements (PMCs), magento-resistive memory elements (e.g., MRAMs), organic memory elements (e.g., ORAMs), or transition metal oxide memory elements (TMOs).

Another type of memory element may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory element may be formed in a manner similar to that described above with reference to phase changing memory elements. A temperature-induced change between an sp³-rich state and an sp³-rich state may be used to change the resistivity of an amorphous carbon material. These differing resistivities may be used to represent different memory states. For example, a high resistance sp³-rich state can be used to represent a “0”, and a low resistance sp²-rich state can be used to represent a “1”. It will be understood that intermediate resistance states may be used to represent multiple bits, as discussed above.

Generally, in this type of carbon memory element, application of a first temperature causes a change of high resistivity sp³-rich amorphous carbon to relatively low resistivity sp²-rich amorphous carbon. This conversion can be reversed by application of a second temperature, which is typically higher than the first temperature. As discussed above, these temperatures may be provided, for example, by applying a current and/or voltage pulse to the carbon material. Alternatively, the temperatures can be provided by using a resistive heater that is disposed adjacent to the carbon material.

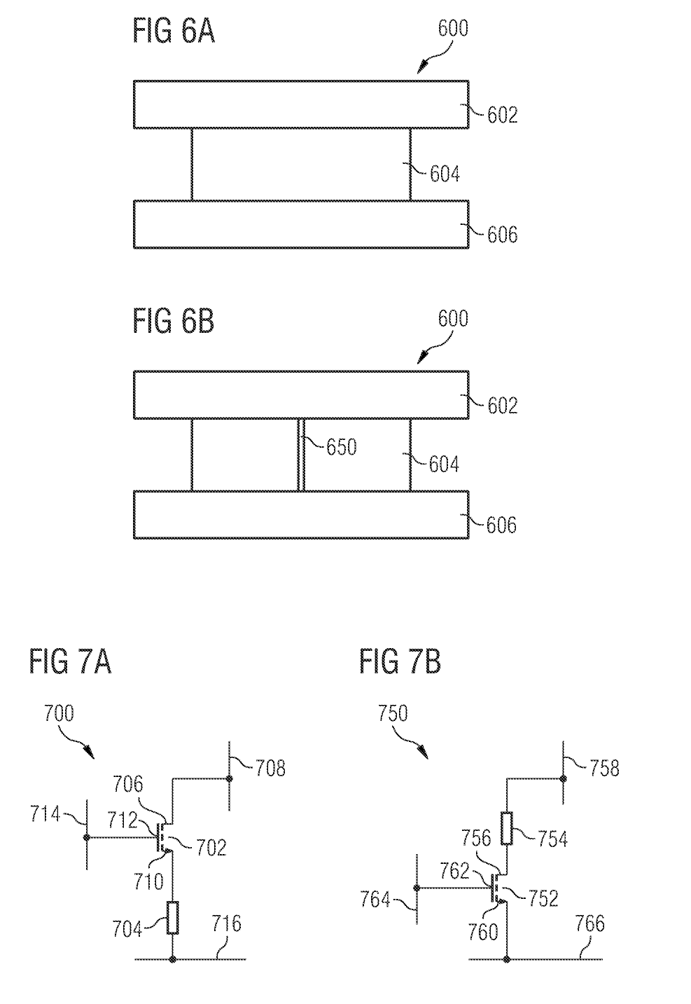

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 6A and 6B.

FIG. 6A shows a carbon memory element 600 that includes a top contact 602, a carbon storage layer 604 including an insulating amorphous carbon material rich in sp³-hybridized carbon atoms, and a bottom contact 606. As shown in FIG. 6B, by forcing a current (or voltage) through the carbon storage layer 604, an sp² filament 650 can be formed in the sp³-rich carbon storage layer 604, changing the resistivity of the memory element. Application of a current (or voltage) pulse with higher energy (or, in some embodiments, reversed polarity) may destroy the sp² filament 650, increasing the resistance of the carbon storage layer 604. As discussed above, these changes in the resistance of the carbon storage layer 604 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory element. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory elements, such as the phase changing memory elements and carbon memory elements described above, may be used as part of a memory cell, along with a transistor, diode, or other active component for selecting the memory cell. FIG. 7A shows a schematic representation of such a memory cell that uses a resistivity changing memory element. The memory cell 700 includes a select transistor 702 and a resistivity changing memory element 704. The select transistor 702 includes a source 706 that is connected to a bit line 708, a drain 710 that is connected to the memory element 704, and a gate 712 that is connected to a word line 714. The resistivity changing memory element 704 also is connected to a common line 716, which may be connected to ground, or to other circuitry, such as circuitry (not shown) for determining the resistance of the memory cell 700, for use in reading. Alternatively, in some configurations, circuitry (not shown) for determining the state of the memory cell 700 during reading may be connected to the bit line 708. It should be noted that as used herein the terms connected and coupled are intended to include both direct and indirect connection and coupling, respectively.

To write to the memory cell 700, the word line 714 is used to select the memory cell 700, and a current (or voltage) pulse on the bit line 708 is applied to the resistivity changing memory element 704, changing the resistance of the resistivity changing memory element 704. Similarly, when reading the memory cell 700, the word line 714 is used to select the cell 700, and the bit line 708 is used to apply a reading voltage (or current) across the resistivity changing memory element 704 to measure the resistance of the resistivity changing memory element 704.

The memory cell 700 may be referred to as a 1T1J cell, because it uses one transistor, and one memory junction (the resistivity changing memory element 704). Typically, a memory device will include an array of many such cells. It will be understood that other configurations for a 1T1J memory cell, or configurations other than a 1T1J configuration may be used with a resistivity changing memory element. For example, in FIG. 7B, an alternative arrangement for a 1T1J memory cell 750 is shown, in which a select transistor 752 and a resistivity changing memory element 754 have been repositioned with respect to the configuration shown in FIG. 7A. In this alternative configuration, the resistivity changing memory element 754 is connected to a bit line 758, and to a source 756 of the select transistor 752. A drain 760 of the select transistor 752 is connected to a common line 766, which may be connected to ground, or to other circuitry (not shown), as discussed above. A gate 762 of the select transistor 752 is controlled by a word line 764.

According to one embodiment of the present invention, an integrated circuit includes a plurality of memory cells, each memory cell including a memory element and a select device. The integrated circuit further includes a plurality of word lines and a plurality of bit lines connected to the memory cells. The bit lines, the word lines and the memory elements are arranged above the select devices.

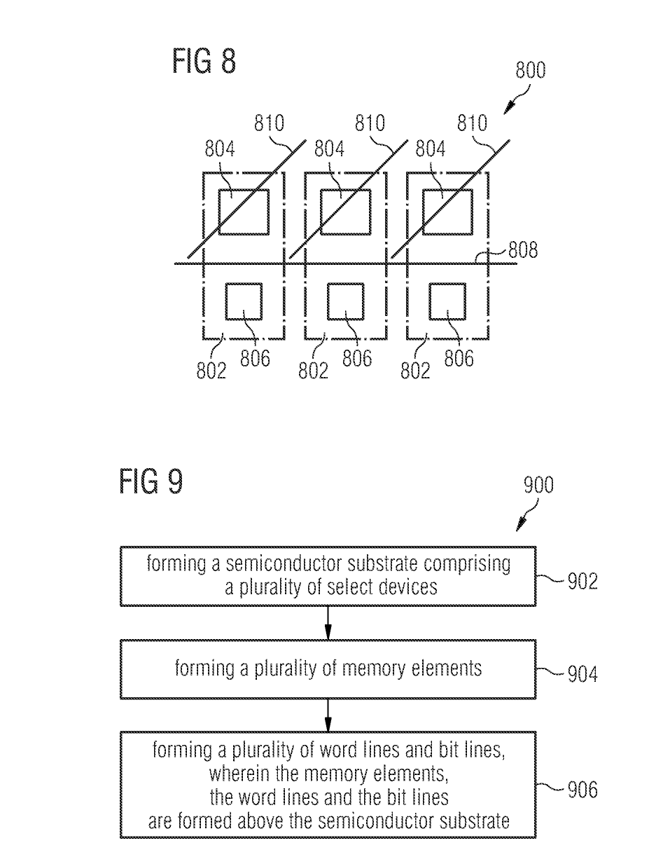

FIG. 8 shows an example 800 of such an integrated circuit. The integrated circuit 800 includes a plurality of memory cells 802, each memory cell 802 including a memory element 804 and a select device 806. The integrated circuit 800 further includes a plurality of word lines 808 and a plurality of bit lines 810 connected to the memory cells 802. The bit lines 810, the word lines 808 and the memory elements 804 are arranged above the select devices 806.

According to one embodiment of the present invention, the select devices are located within a common semiconductor substrate shared by all memory cells. One effect of this embodiment is that it is possible to form bit lines and word lines having a low resistance since they can be formed above, but not within the common semiconductor substrate; therefore, the bit lines/word lines can be made of metal (low resistance) and do not have to be formed as buried semiconductor lines (high resistance). Since the formation of word lines and bit lines above the common semiconductor substrate is easier than the formation of buried word lines/bit lines within the semiconductor substrate, a further effect of this embodiment is that the manufacturing process can be facilitated.

According to one embodiment of the present invention, the semiconductor substrate is divided into a plurality of active areas which are at least partly isolated against each other, wherein each active area includes two select devices, and wherein above each active area two memory elements are arranged.

According to one embodiment of the present invention, the select devices provided within the same active area are connected to a common word line, wherein the memory elements arranged above the same active area are connected to individual bit lines. It should be mentioned that the terms “word line” and “bit line” should not be interpreted as being restrictive: the select devices provided within the same active area may also be connected to a common bit line, and the memory elements arranged above the same active area may also be connected to individual word lines.

According to one embodiment of the present invention, the select devices provided within the same active area share a common part of the active area.

According to one embodiment of the present invention, the select devices are diodes. According to one embodiment of the present invention, a first end of each diode is connected to a memory element, and a second end of each diode is connected to the common word line. According to one embodiment of the present invention, the common part is a common word line/bit line contacting area.

It has been assumed in the foregoing description that the select devices are diodes. However, the present invention is not restricted thereto. For example, the select devices may also be bipolar transistors. One effect of choosing diodes and bipolar transistors as select devices is that the dimensions of the select devices can be kept very compact since even compact diodes and bipolar transistors are able to carry high current densities. In contrast, select devices like field effect transistors (e.g., MOSFETs) are only able to carry small current densities when they are scaled down.

In case that bipolar transistors are chosen as select devices, each bipolar transistor may comprise a emitter connected to a memory element, a base connected to the common word line, and a collector. Here, the common part shared by the select devices may, for example, be word line/bit line contacting area. According to one embodiment of the present invention, the collector is a common collector which is shared by all select devices. One effect of a common collector is that the electrical resistance of the collector is very low due to its large dimensions. Thus, driving voltages driving writing currents/sensing currents through the memory elements can be reduced.

According to one embodiment of the present invention, the common part shared by the select devices is arranged between the select devices, and is laterally isolated against the select devices. The common part may also be a part of the select devices itself.

According to one embodiment of the present invention, the memory elements are resistivity changing memory elements. For example, the memory elements may be phase changing memory elements, magneto-resistive memory elements, programmable metallization memory elements, carbon memory elements, transition metal oxide memory elements, or the like.

According to one embodiment of the present invention, a memory module including at least one integrated circuit is provided. Each integrated circuit includes: a plurality of memory cells, each memory cell including a memory element and a select device; and a plurality of word lines and bit lines connected to the memory cells, wherein the bit lines, the word lines, and the memory elements are arranged above the select devices. According to one embodiment of the present invention, the memory modules are stackable.

FIG. 9 shows a flowchart of a method 900 of manufacturing an integrated circuit according to one embodiment of the present invention.

At 902, a semiconductor substrate including a plurality of select devices is formed. At 904, a plurality of memory elements are formed. At 906, a plurality of word lines and bit lines are formed, wherein the memory elements, the word lines and the bit lines are formed above the semiconductor substrate.

According to one embodiment of the present invention, the formation of the semiconductor substrate includes forming an isolation structure within the semiconductor substrate such that the semiconductor substrate is divided into a plurality of active areas which are at least partly isolated against each other.

According to one embodiment of the present invention, the semiconductor substrate is formed such that each semiconductor layer includes a plurality of semiconductor layers stacked above each other.

According to one embodiment of the present invention, an isolation structure is formed within each active area such that the active area is split into two parts which are laterally isolated against each other by the isolation structure, wherein the plurality of semiconductor layers of each part respectively forms a select device.

According to one embodiment of the present invention, the isolation structure within an active area is formed by: forming a trench within the active area extending at least through the top semiconductor layer; covering the side walls of the trench with isolation material; and filling remaining space within the trench with conductive material.

According to one embodiment of the present invention, a word line is formed above the semiconductor substrate which contacts the conductive material filled into the trench.

According to one embodiment of the present invention, two memory elements are formed above each active area, wherein each memory element is connected to the top layer of a select device (top layer of the plurality of semiconductor layers).

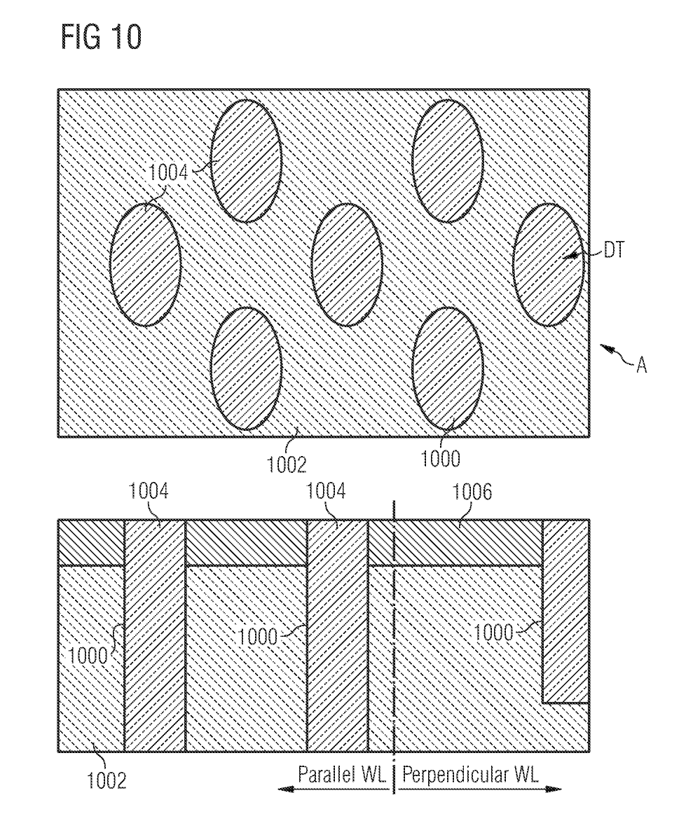

In the following description, making reference to FIG. 10 to 30, a method of manufacturing an integrated circuit according to one embodiment of the present invention will be explained.

Within FIGS. 10 to 15 and 21 to 29, the upper part of each Figure shows a top view of the manufacturing stage, whereas the lower parts and/or the right part of the Figure respectively show different cross-sectional views of the manufacturing stage.

FIG. 10 shows a manufacturing stage A obtained after having formed trenches 1000 within a semiconductor substrate 1002, e.g., a silicon substrate covered with an isolation layer 1006, e.g., an Si₃N₄ layer. The trenches 1000 have been filled with isolation material 1004, for example oxide. The semiconductor substrate comprises a plurality of semiconductor layers. The depth of the trenches 1000 may, for example, be about 400 nm or about 800 nm.

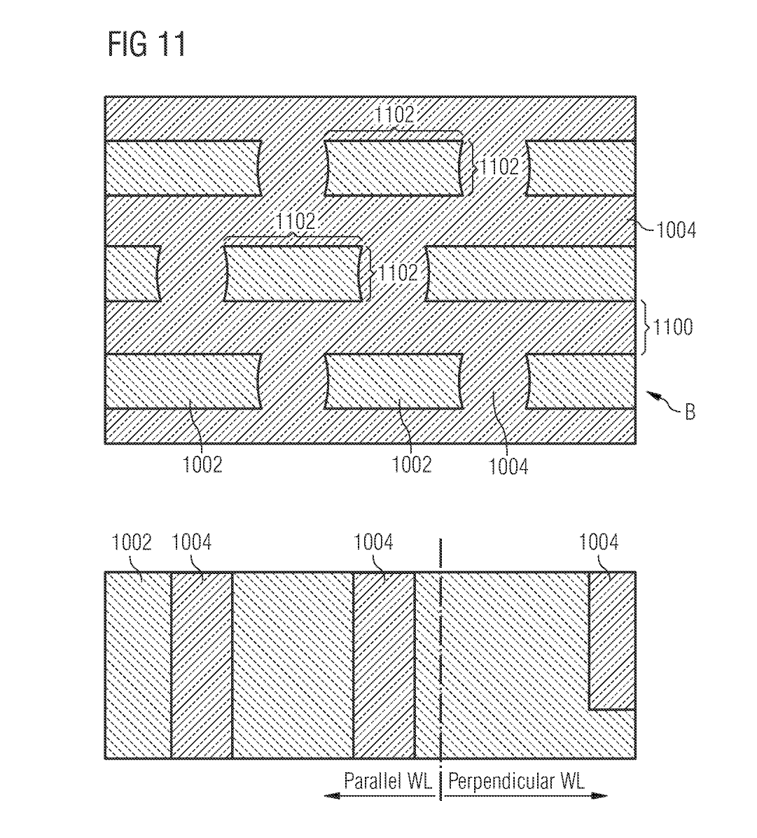

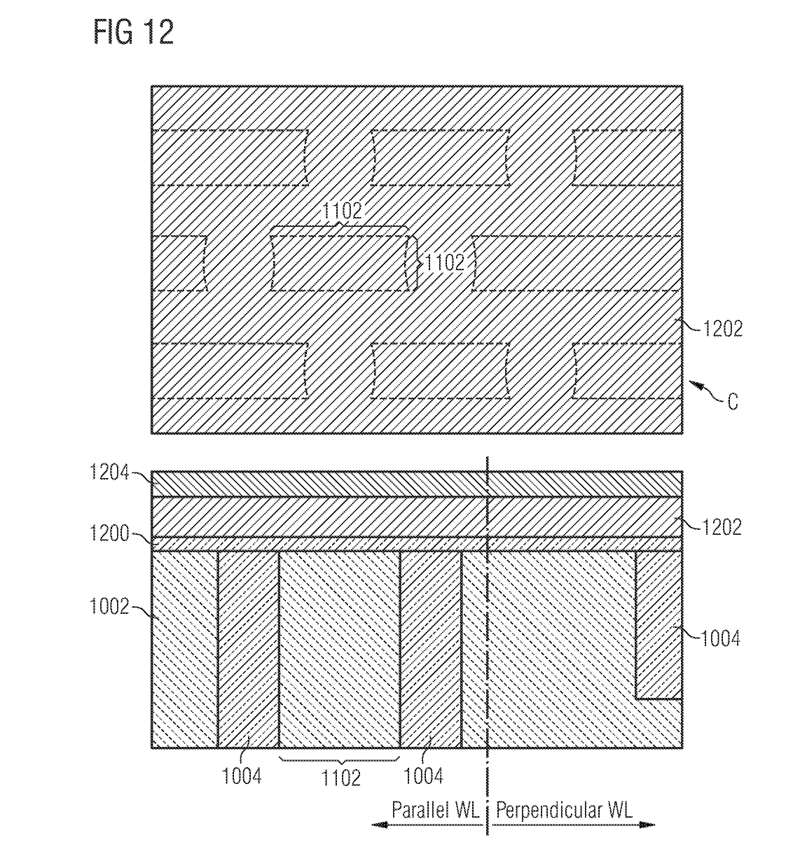

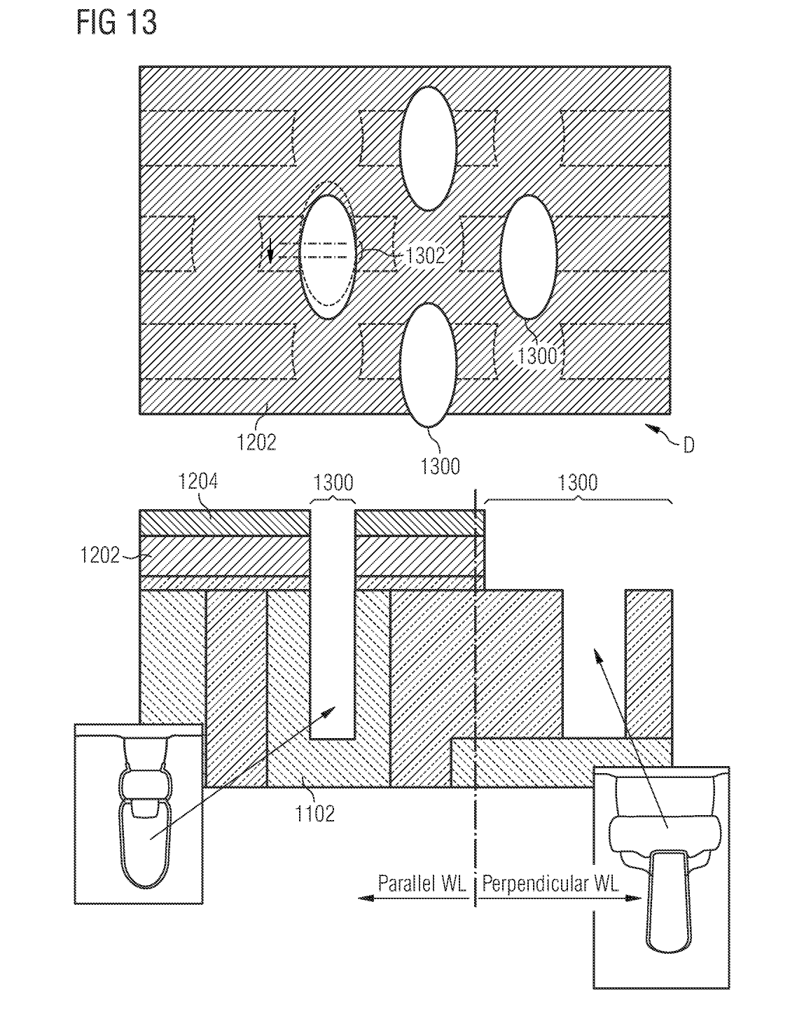

FIG. 11 shows a manufacturing stage B obtained after having formed further trenches 1100 filled with isolation material 1004, e.g., oxide. In this way, active areas 1102 are formed which are laterally surrounded by isolation material 1004. The depth of the trenches 1100 may, for example, be about 400 nm or about 800 nm. A planarization process has been carried out in order to expose the top surface of the semiconductor substrate 1002.

FIG. 12 shows a manufacturing stage C obtained after having formed an isolation layer 1200 (here: an oxide layer), a first conductive layer 1202 (here: a polysilicon layer), and an isolation layer 1204 (here: an oxide layer or nitride layer, e.g., Si₃N₄) in this order on the semiconductor substrate 1002.

FIG. 13 shows a manufacturing stage D obtained after having formed trenches 1300 which respectively extend through the isolation layer 1204, the first conductive layer 1202, and the isolation layer 1200 into the semiconductor material of an active area 1102.

The formation of the trenches 1300 may for example be carried out using an etching process. It should be mentioned that the positions of the trenches 1300 are not vertically centered with regard to the active areas 1102; instead, as shown in FIG. 13, the trenches 1300 are shifted downwards by a shifting distance 1302.

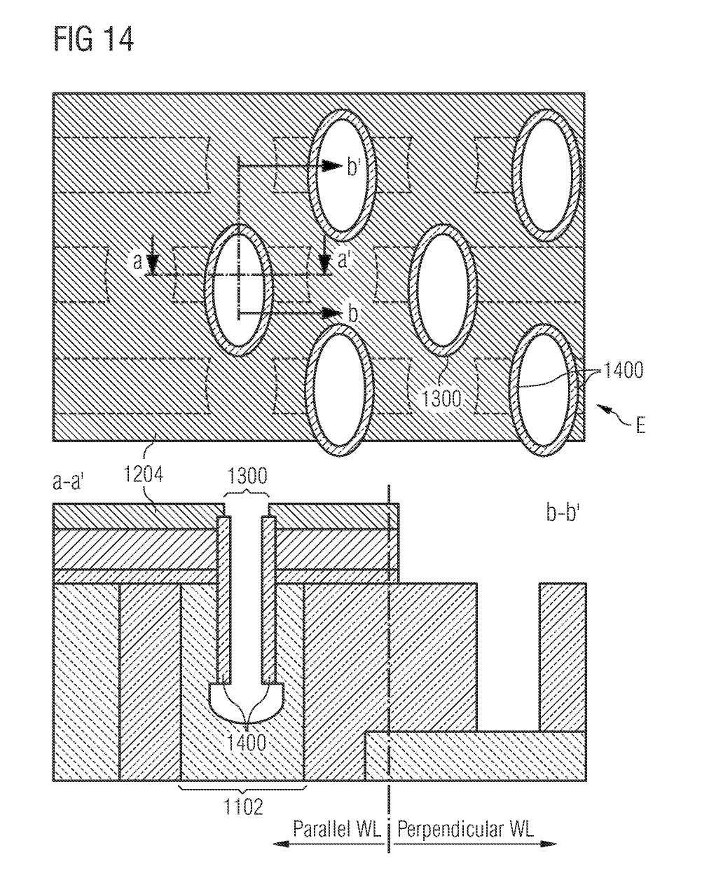

FIG. 14 shows a manufacturing stage E obtained after having covered the inner walls of the trenches 1300 with isolation material (spacer) 1400. The bottom of the trenches 1300 are not covered with isolation material. An etching process (optional) may be carried out which etches the material of the semiconductor substrate 1002, however does not etch the isolation material 1400. In this way, an enlargement of the trench 1300 at its lower end, as shown in FIG. 14, is obtained. The area around the bottom end of the trench 1300 (area which is not covered by the isolation material 1400) may be doped with doping material to become a n⁺ conductive or a p⁺ conductive semiconducting area, for example. The doping process may be carried out by introducing doping material into the trenches 1300.

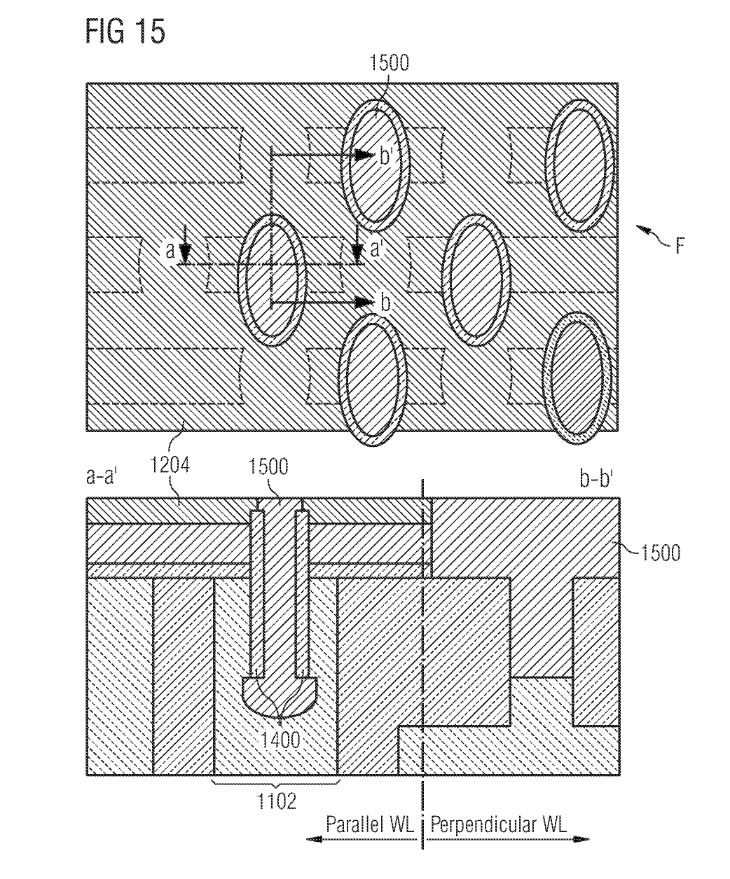

FIG. 15 shows a manufacturing stage F obtained after having filled the trenches 1300 with conductive material 1500 (here: poly silicon material). Further, a planarization process has been carried out in order to expose the top surface of the isolation layer 1204. The planarization process may, for example, be carried out using a chemical mechanical polishing process (CMP process), or a reactive ion etching process (RIE process). Alternatively, an epitaxy process may be carried out in order to fill the trenches 1300 with n semiconducting or p semiconducting material.

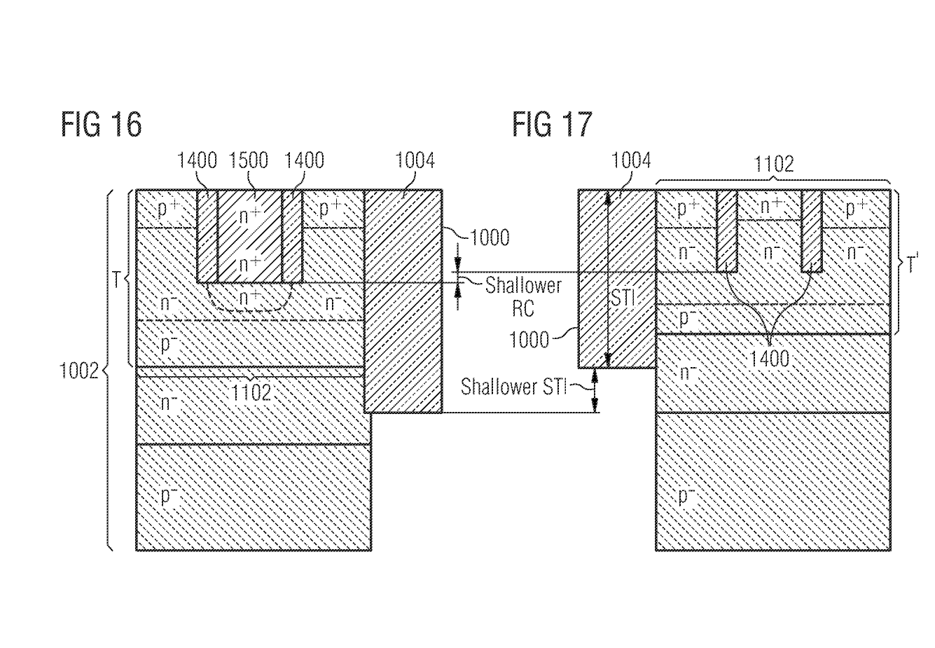

In this way, a semiconductor substrate 1002 as shown in FIG. 16 may be obtained. It is assumed here that the semiconductors substrate 1002 includes a p⁻ layer, n⁻ layer, p⁻ layer, n⁻ layer, and p⁺ layer which are stacked above each other in this order. However, the embodiments of the present invention are not restricted thereto; also other types of layer architectures may be used.

Here, the conductive material 1500 is n⁺ polysilicon. As can be derived from FIG. 16, this embodiment requires a relatively deep trench 1000, i.e. a relatively deep active area isolation structure.

In contrast, as shown in FIG. 17, it is also possible to fill the trenches 1300 using an epitaxy process, as mentioned above. This process should be carried out at low temperature. For example, as shown in FIG. 17, the trenches 1300 may be filled with a layer of n− doped semiconducting material, followed by a layer of n+ doped semiconducting material. One effect of the embodiment shown in FIG. 17 is that the depth of the trench 1000, i.e., of the active area isolation structure can be reduced. However, problems may be caused by parasitic bipolar effects. A further effect of the embodiment shown in FIG. 17 is that the thickness T′ of the active area 1102 is reduced, compared to the thickness T of the active area 1102 shown in FIG. 16. However, the embodiment shown in FIG. 16 is easier to manufacture than the embodiment shown in FIG. 17.

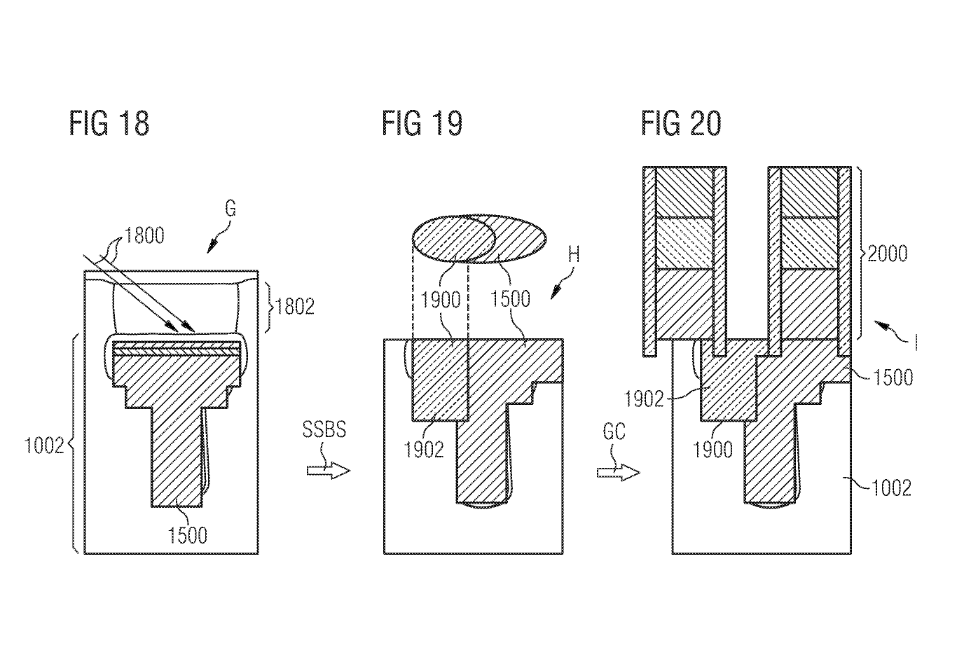

FIG. 18 shows a manufacturing stage G which is an enlarged view of the bottom right part of FIG. 15. Further, a masking layer 1802 has been deposited on the substrate 1002 having the same pattern as that used for forming the trenches 1300.

FIG. 19 shows a manufacturing stage H obtained after having replaced a part of the conductive material 1500 by isolation material 1900. The removal of the conductive material 1500 may for example be carried out as follows: A part of the conductive material 1500 is doped with doping material, for example boron. After this, a selective etching process is carried out which selectively etches the boron doped conductive material 1500 over the undoped conductive material 1500, or vice versa. In this way, no extra mask is needed for forming the isolation material 1900 (the masking layer 1802 which has been deposited on the substrate 1002 has the same pattern as that used for forming the trenches 1300): The introduction of doping material may for example be carried out by subjecting the masking layer 1802 to ion beams including or consisting of the doping material. Since the top surface of the conductive material 1500 is lower than the top surface of the masking layer 1802, a partial exposure of the top surface of the conductive material 1500 may for example be achieved by using ion beams having a declined angle, as indicated by the arrows 1800 in FIG. 18 (single side buried strap (SSBS) method). Alternatively, an additional mask (masking layer having a different pattern as that used for forming the trenches 1300) may be used in order to define a trench 1902 into which later the isolation material 1900 can be filled. In order to form the trench 1902, for example, an etching process may be used. In this case, manufacturing stage G can be omitted.

FIG. 20 shows a manufacturing stage I obtained after having formed word lines 2000 (the formation of which will be explained later) which contact the conductive material 1500 filled into the trenches 1300. The word lines 2000 are isolated against each other by the oxide filled trenches 1900.

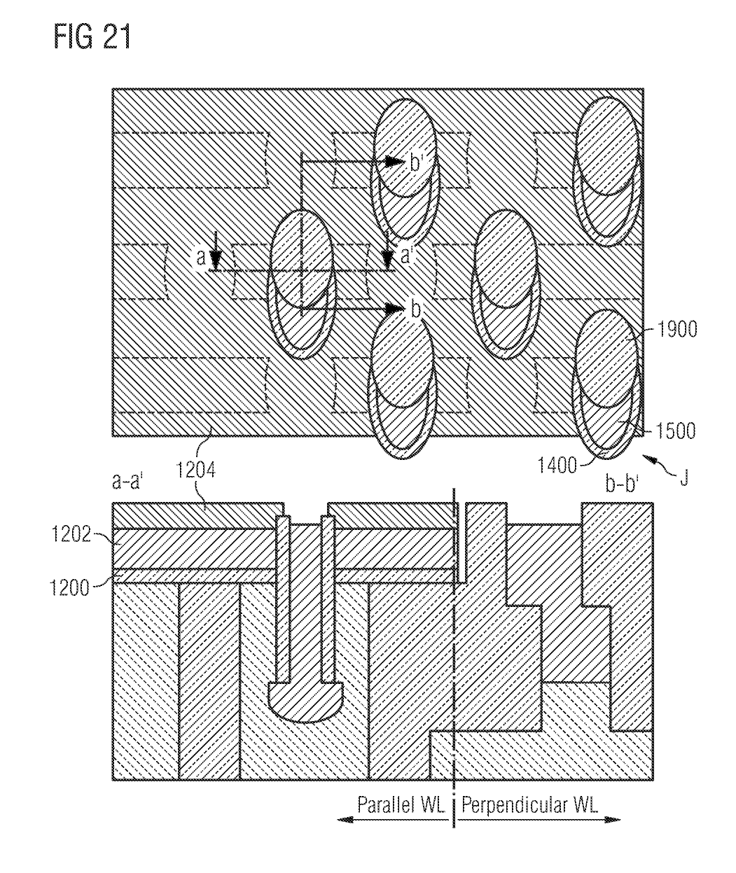

FIG. 21 shows a manufacturing stage J obtained after having carried out the processes shown in FIGS. 18 to 19.

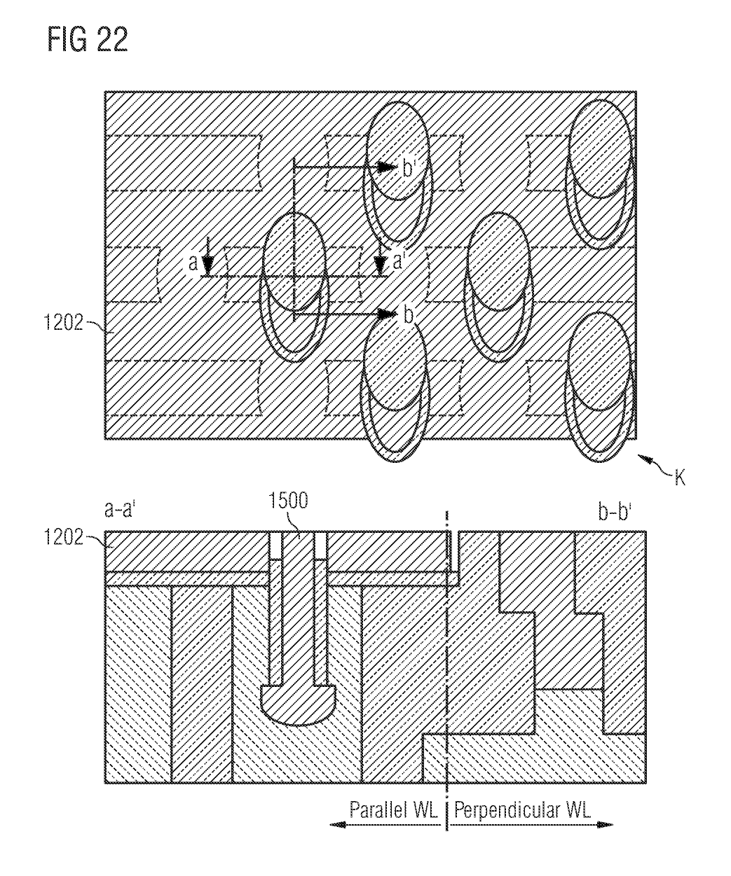

FIG. 22 shows a manufacturing stage K obtained after having removed the isolation layer 1204.

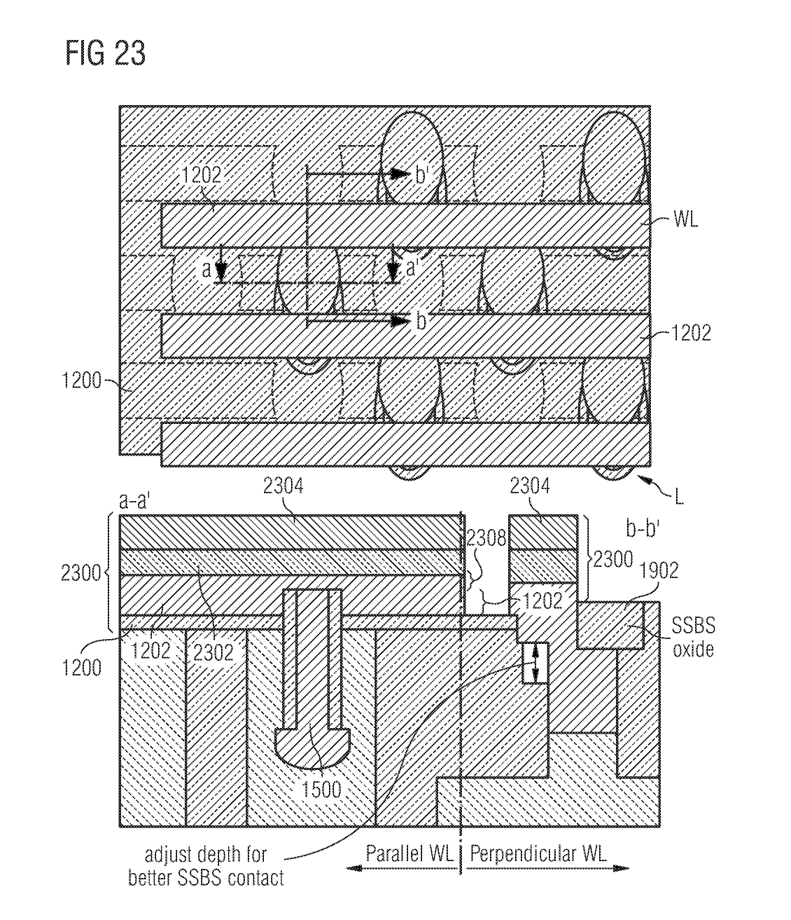

FIG. 23 shows a manufacturing stage L obtained after having formed word line stacks 2300 including a word line contact layer 2308 (the first conductive layer 1202 and a second conductive layer 2308 (here: a semiconductive layer)), the conductive layer 2302 (here: a metal layer, e.g., a WSi layer), and an isolation layer 2304 (cap layer, for example a SiN layer).

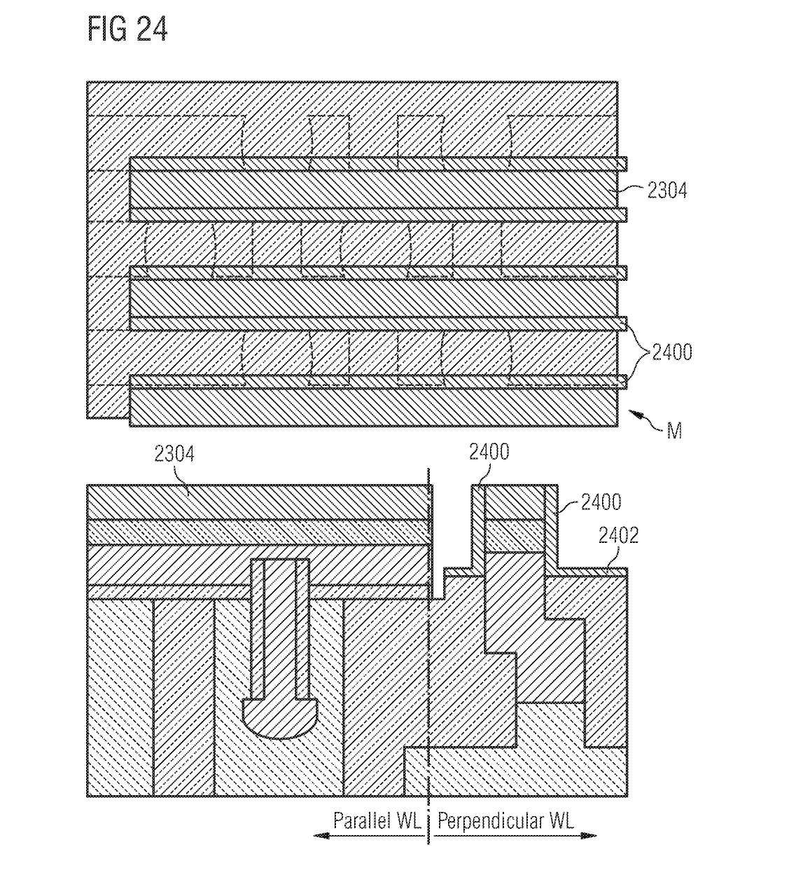

FIG. 24 shows a manufacturing stage M obtained after having formed spacers 2400 which may for example consist of Si3N4 or oxide, and which cover the side walls of the word line stacks 2300. The spacers 2400 are formed such that isolation material 2402 (spacer material deposited during the spacer formation) covers the areas between the word line stacks 2300.

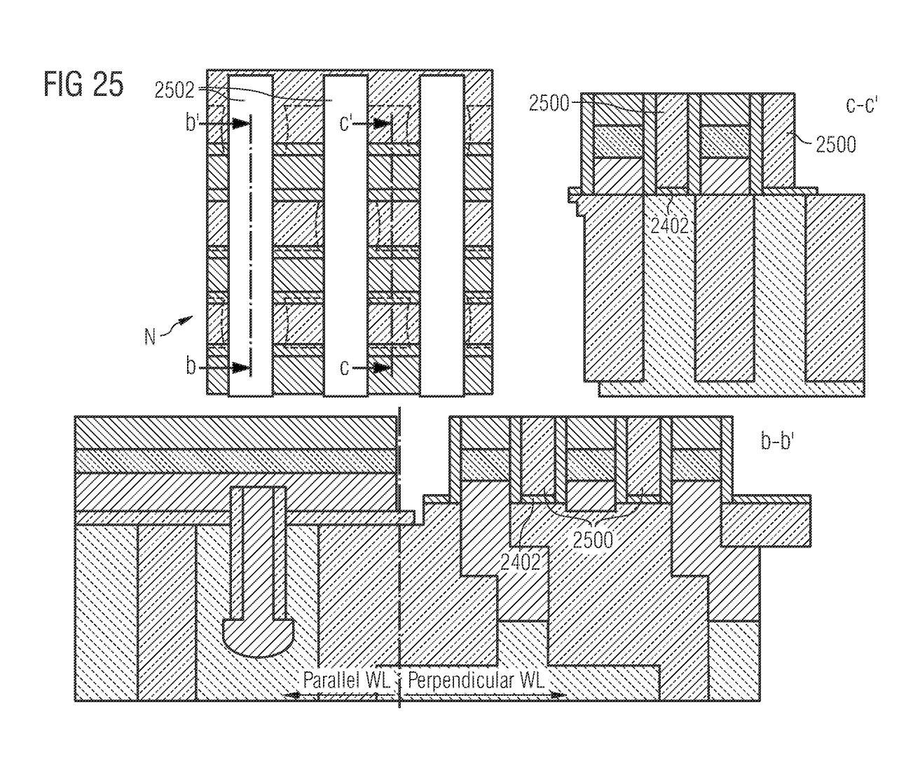

FIG. 25 shows a manufacturing stage N obtained after having filled the space between the word line stacks 2300 with isolation material 2500 (e.g., oxide), and after having carried out a planarization process (e.g., CMP process). Further, a patterning mask 2502 has been deposited. The patterning mask consists of stripes being arranged perpendicular to the word line stacks 2300.

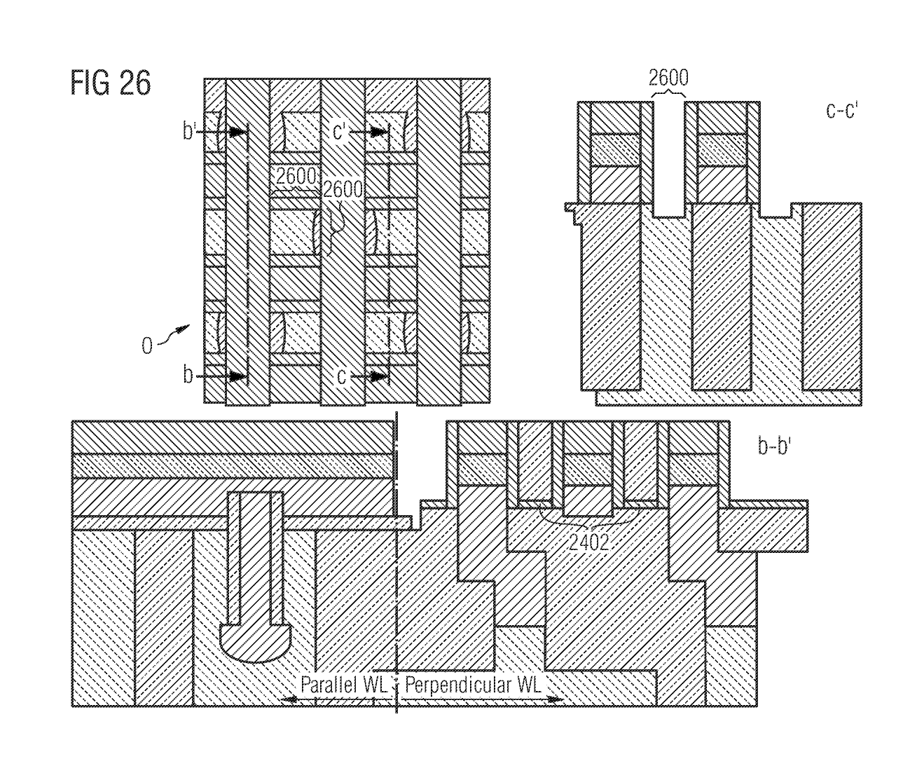

FIG. 26 shows a manufacturing stage O obtained after having carried out an etching process using the word line stacks 2300 and the patterning mask 2502 as an etching mask. In this way, trenches 2600 are formed within the isolation material 2500. Then, a further etching process is carried out in order to remove the isolation material 2402 within the trenches 2600, thereby exposing the top surface of the semiconductor substrate 1002. Then, the patterning mask 2502 is removed.

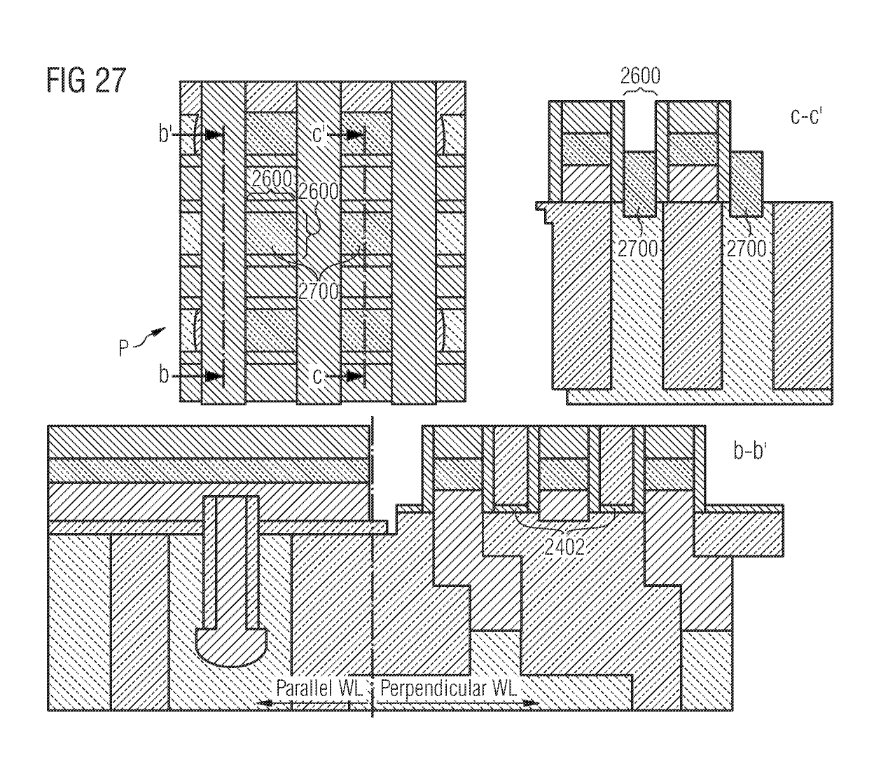

FIG. 27 shows a manufacturing stage P obtained after having filled the bottom part of the trenches 2600 with conductive material 2700, e.g., by depositing a layer of conductive material 2700, by carrying out a planarization process of the conductive material 2700, and by carrying out an etch back process of the conductive material 2700 into the trenches 2600.

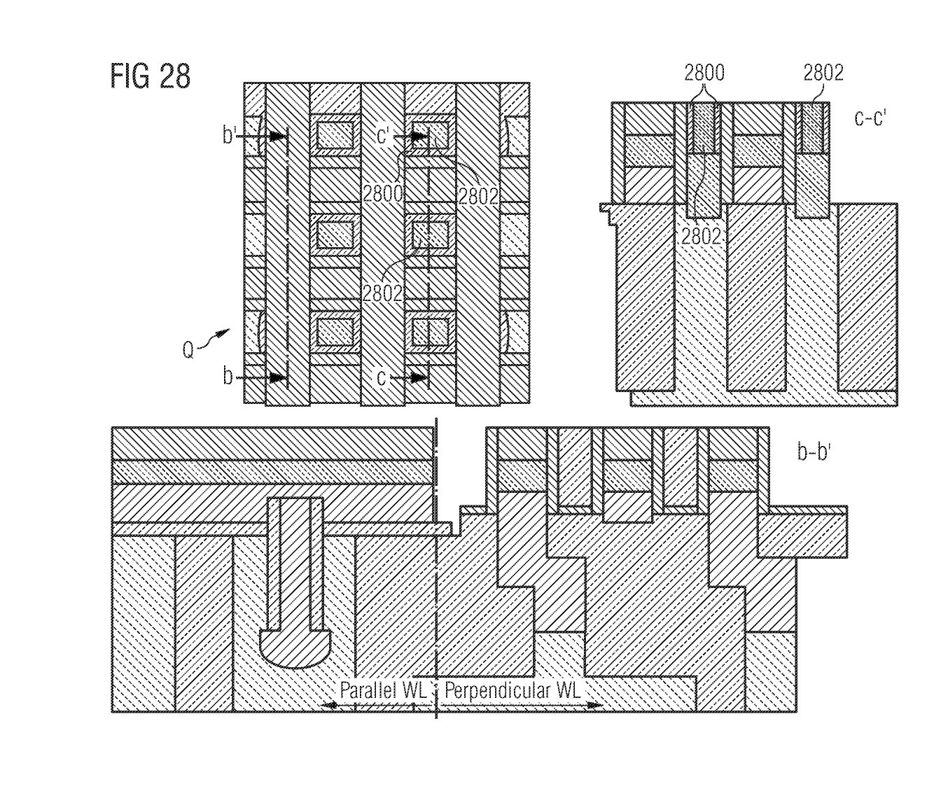

FIG. 28 shows a manufacturing stage Q obtained after having formed spacers 2800 (e.g., oxide spacers) within the upper part of the trenches 2600, and after having filled the remaining space within the trenches 2600 with heating a material 2802, for example, TiN. Then, a planarization process may be carried out.

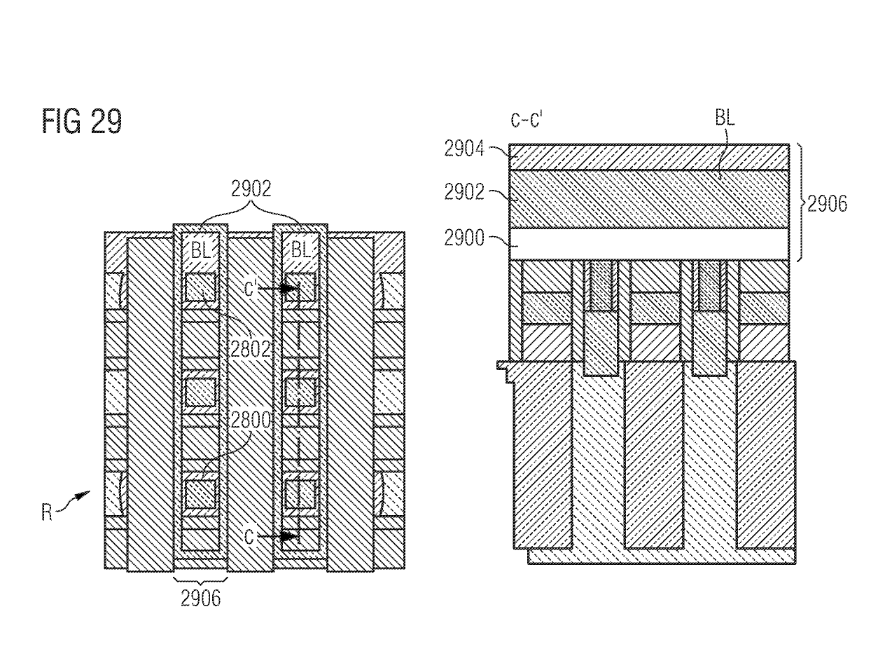

FIG. 29 shows a manufacturing stage R obtained after having deposited a resistivity changing layer 2900, a bit line layer 2902 (e.g., a WSi layer), and a masking layer 2904 (e.g., an oxide layer) in this order above each other. Then, the masking layer 2904 is patterned and used as mask for patterning the bit line layer 2902 and the resistivity changing layer 2900 (for example, the phase changing material layer). In this way, bit line stacks 2906 are formed. Isolation material may be filled between the bit line stacks 2906.

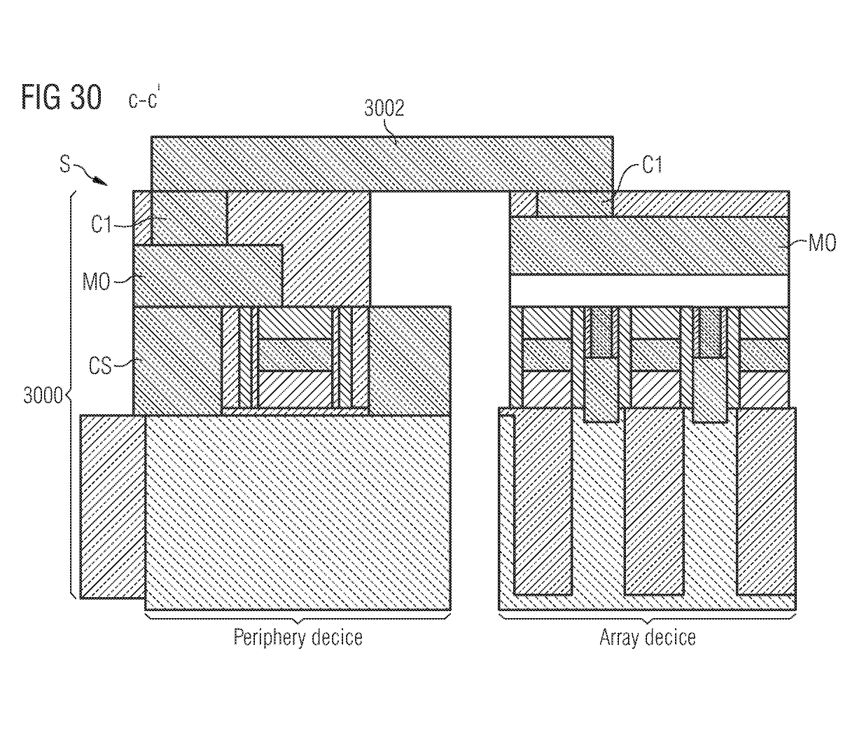

FIG. 30 shows a manufacturing stage S obtained after having connected the integrated circuit thus obtained with a periphery device 3000 (which may be formed simultaneously to the formation of the memory device as explained above) via metal connections 3002. That is, the bit lines 2902 are contacted by electrical connection 3002. The formation of the periphery device 3000 may be similar to the formation of a periphery device of a standard DRAM memory device and is therefore not explained in detail.

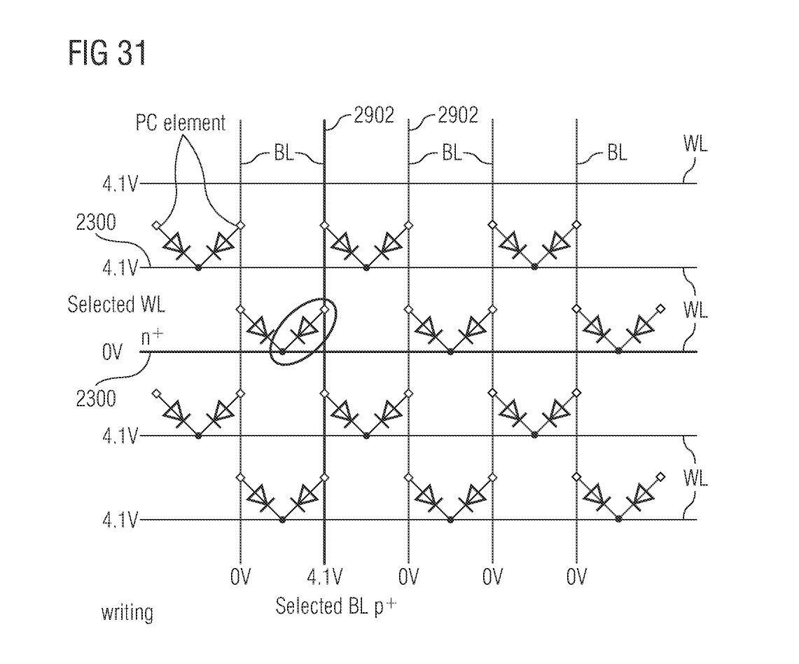

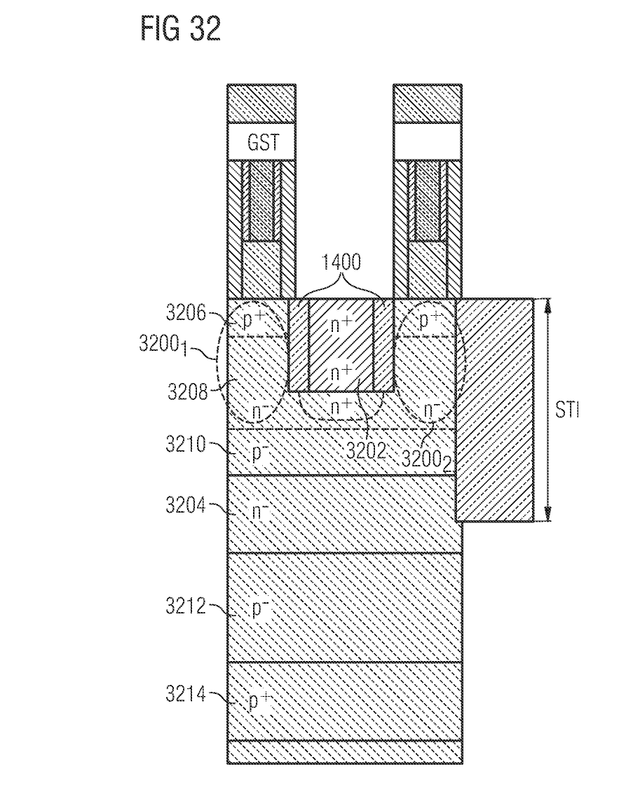

FIG. 31 shows the equivalent circuit of an integrated circuit manufactured as explained in conjunction with FIGS. 10 to 30. FIG. 32 shows a cross-sectional view of a “cell unit” (the “cell unit” comprises two memory cells), i.e., the repeating pattern unit of the integrated circuit. Within the cell unit, two select devices 32001, 32002 share a common word line contact 3202. The common word line contact 3202 is laterally isolated against the select devices 32001, 32002 by isolation material 1400. Each select device includes a p+ semiconductor layer 3206 and a n− semiconductor layer 3208.

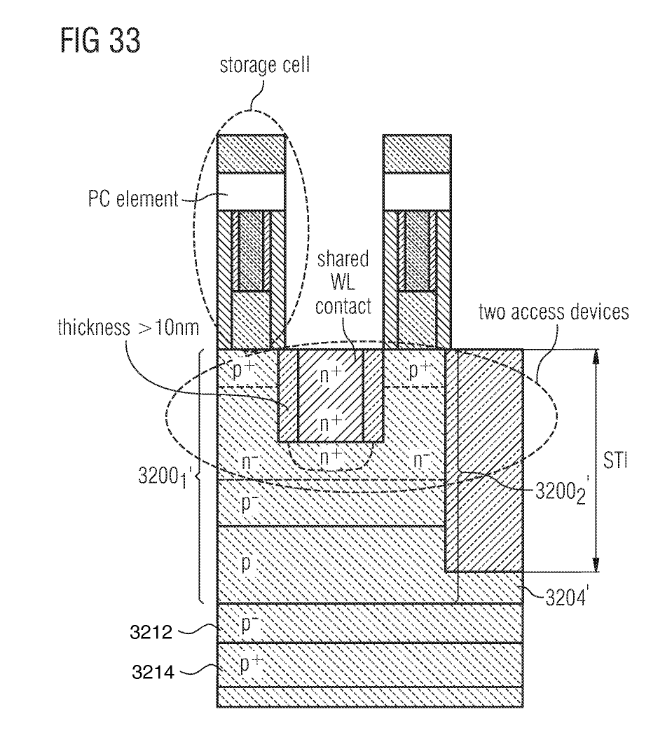

In the embodiment shown in FIG. 32, the select devices 32001, 32002 are diodes. However, the invention is not restricted thereto. For example, as shown in FIG. 33, the select devices may also be bipolar transistors 3200′1, 3200′2. In this case, the n doped semiconductor layer denoted by reference numeral 3204 may be replaced by a p doped semiconductor layer 3204′ in order to form a common collector; the semiconductor layer 3206 would form the emitter; the semiconductor layer 3208 would form the base; and the layers 3210, 3204′ would form the collector. Further, the semiconductor layers 3212, 3214 may also be interpreted as collector layers.

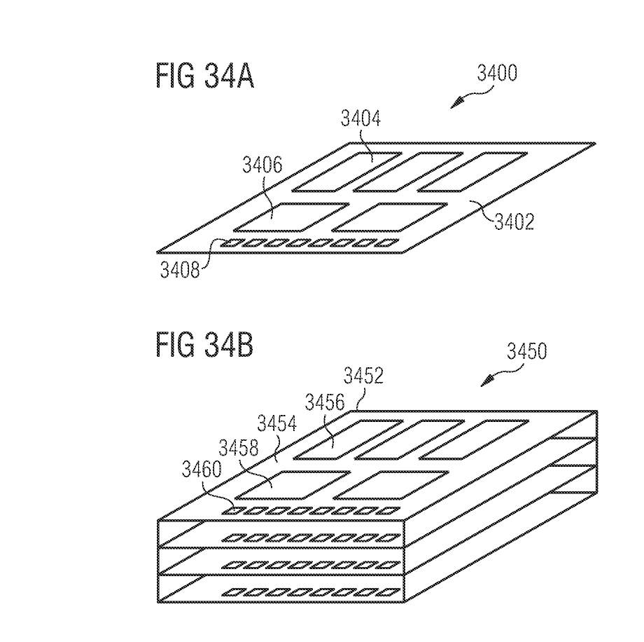

As shown in FIGS. 34A and 34B, in some embodiments, integrated circuits such as those described herein may be used in modules. In FIG. 34A, a memory module 3400 is shown, on which one or more integrated circuits 3404 are arranged on a substrate 3402. The integrated circuits 3404 may include numerous memory cells. The memory module 3400 may also include one or more electronic devices 3406, which may include memory, processing circuitry, control circuitry, addressing circuitry, bus interconnection circuitry, or other circuitry or electronic devices that may be combined on a module with a memory device, such as the integrated circuit 3404. Additionally, the memory module 3400 includes multiple electrical connections 3408, which may be used to connect the memory module 3400 to other electronic components, including other modules.

As shown in FIG. 34B, in some embodiments, these modules may be stackable, to form a stack 3450. For example, a stackable memory module 3452 may contain one or more integrated circuits 3456, arranged on a stackable substrate 3454. The integrated circuits 3456 contain memory cells that employ memory elements. The stackable memory module 3452 may also include one or more electronic devices 3458, which may include memory, processing circuitry, control circuitry, addressing circuitry, bus interconnection circuitry, or other circuitry or electronic devices that may be combined on a module with a memory device, such as the integrated circuits 3456. Electrical connections 3460 are used to connect the stackable memory module 3452 with other modules in the stack 3450, or with other electronic devices. Other modules in the stack 3450 may include additional stackable memory modules, similar to the stackable memory module 3452 described above, or other types of stackable modules, such as stackable processing modules, control modules, communication modules, or other modules containing electronic components.

Within the scope of the present invention, the terms “connecting” and “coupling” may both mean direct and indirect connecting/coupling.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit, comprising:
a plurality of memory cells, each memory cell comprising a memory element and a select device;
a plurality of word lines coupled to the memory cells; and
a plurality of bit lines coupled to the memory cells, wherein the bit lines, the word lines, and the memory elements are arranged above the select devices.

2. The integrated circuit according to claim 1, wherein the select devices are located within a common semiconductor substrate shared by all memory cells.

3. The integrated circuit according to claim 2, wherein the semiconductor substrate is divided into a plurality of active areas that are at least partly isolated against each other, wherein each active area comprises two select devices, and wherein two memory elements are arranged above each active area.

4. The integrated circuit according to claim 3, wherein the select devices provided within the same active area are coupled to a common word line, and wherein the memory elements arranged above the same active area are coupled to individual bit lines.

5. The integrated circuit according to claim 4, wherein select devices provided within the same active area share a common part of the active area.

6. The integrated circuit according to claim 5, wherein the select devices comprise diodes.

7. The integrated circuit according to claim 6, wherein a first end of each diode is coupled to a memory element, and wherein a second end of each diode is coupled to the common word line.

8. The integrated circuit according to claim 7, wherein the common part of the active area is a common word line contacting area.

9. The integrated circuit according to claim 5, wherein the select devices comprise bipolar transistors.

10. The integrated circuit according to claim 9, wherein each bipolar transistor comprises an emitter connected to a memory element, a base connected to the common word line, and a collector.

11. The integrated circuit according to claim 10, wherein the common part of the active area is a word line contacting area.

12. The integrated circuit according to claim 11, wherein the collector is a common collector shared by all select devices.

13. The integrated circuit according to claim 5, wherein the common part of the active area is arranged between the select devices, and is laterally isolated against the select devices.

14. The integrated circuit according to claim 1, wherein the memory elements comprise resistivity changing memory elements.

15. The integrated circuit according to claim 1, wherein the memory elements comprise phase changing memory elements.

16. The integrated circuit according to claim 1, wherein the memory elements comprise magneto-resistive memory elements.

17. The integrated circuit according to claim 1, wherein the memory elements comprise programmable metallization memory elements.

18. A memory module comprising at least one integrated circuit comprising:
a plurality of memory cells, each memory cell comprising a memory element and a select device; and
a plurality of word lines and bit lines connected to the memory cells,
wherein the bit lines, the word lines, and the memory elements are arranged above the select devices.

19. A method of manufacturing an integrated circuit, the method comprising:
providing a semiconductor substrate comprising a plurality of select devices;
forming a plurality of memory elements over the semiconductor substrate; and
forming a plurality of word lines and bit lines above the semiconductor substrate;
wherein the memory elements, the word lines and the bit lines are formed above the select devices.

20. The method according to claim 19, wherein providing the semiconductor substrate comprises forming an isolation structure within the semiconductor substrate such that the semiconductor substrate is divided into a plurality of active areas which are at least partly isolated from each other.

21. The method according to claim 20, wherein each active area comprises a plurality of semiconductor layers stacked above each other.

22. The method according to claim 21, wherein the isolation structures are formed within each active area such that the active area is split into two parts that are laterally isolated against each other by the isolation structure, the plurality of semiconductor layers of each part respectively forming a select device.

23. The method according to claim 22, forming the isolation structure comprises:
forming a trench within the active area extending at least through a top semiconductor layer of the active area;
covering side walls of the trench with isolation material; and
filling remaining space within the trench with conductive material.

24. The method according to claim 23, wherein each word line is connected to the conductive material filled into a respective trench.

25. The method according to claim 22, wherein two memory elements are formed above each active area, wherein each memory element is connected to a top semiconductor layer of a select device.
